(19) United States
(12) Patent Application Publication
(10) Pub. No.: US 2024/0234505 A1
(43) Pub. Date: Jul. 11, 2024

(54) SEMICONDUCTOR DEVICE AND FABRICATION METHOD THEREOF

(71) Applicant: UNITED MICROELECTRONICS CORP., Hsin-Chu City (TW)

(72) Inventors: Hsu Ting, Tainan City (TW); Kuang-Hsiu Chen, Tainan City (TW); Shou-Hung Wu, Kaohsiung City (TW); Shao-Wei Wang, Taichung City (TW); Yu-Ren Wang, Tainan City (TW)

(73) Assignee: UNITED MICROELECTRONICS CORP., Hsin-Chu City (TW)

(21) Appl. No.: 18/105,887

(22) Filed: Feb. 6, 2023

(30) Foreign Application Priority Data
Jan. 11, 2023 (TW) 112101143

(51) Int. Cl. H01L 29/08; H01L 21/02; H01L 29/165; H01L 29/66; H01L 29/78

(52) U.S. Cl. CPC H01L 29/0847; H01L 21/02532; H01L 29/165; H01L 29/66795; H01L 29/7848; H01L 29/7851

(57) ABSTRACT

A semiconductor device includes a fin structure disposed on a substrate, and an epitaxial semiconductor layer disposed over an upper part of the fin structure and having an undercut. The epitaxial semiconductor layer has a right-left symmetric, concave polygonal cross-section.

### BACKGROUND OF THE INVENTION

### 1. Field of the Invention

The invention relates to the field of semiconductor technology, in particular to an improved fin field effect transistor (finFET) device and a manufacturing method thereof.

### 2. Description of the Prior Art

It is known in the art that compressive stress increases carrier mobility of P-channel metal-oxide-semiconductor (PMOS) devices. One approach of introducing compressive stress in the PMOS transistor channel region includes growing an epitaxial layer of SiGe within recesses in the source/drain regions. In this approach, lattice mismatch between the epitaxial SiGe and the silicon substrate creates a uni-axial compressive stress within the channel region.

High germanium concentration in epitaxial silicon germanium may be needed to effectively boost channel compressive strain in PMOS devices. As the germanium concentration is increased, a level of uniaxial compressive strain occurring in the channel region may be further increased. Such uniaxial compressive strain may increase a degree of mobility of holes in the channel region of the PMOS transistor. However, as the Ge concentration increases in SiGe, high-density defects are generated, which limit its applications.

### SUMMARY OF THE INVENTION

One object of the present invention is to provide an improved semiconductor transistor device and a fabrication method thereof to solve the deficiencies or shortcomings of the prior art.

One aspect of the invention provides a semiconductor device including a fin structure disposed on a substrate; and an epitaxial semiconductor layer disposed over an upper part of the fin structure and having an undercut.

According to some embodiments, the fin structure protrudes from the substrate in a first direction and the undercut has a surface parallel to a third direction perpendicular to the first direction.

According to some embodiments, the undercut comprises a curved surface.

According to some embodiments, the substrate comprises silicon.

According to some embodiments, the fin structure comprises silicon.

According to some embodiments, the semiconductor device is a PMOS transistor and the epitaxial semiconductor layer comprises compressively stressed silicon germanium.

According to some embodiments, the semiconductor device further includes an oxide liner layer conformally covering the undercut; and an isolation structure around the fin structure, wherein the oxide liner layer is in direct contact with the isolation structure.

According to some embodiments, the oxide liner layer comprises silicon dioxide.

According to some embodiments, the oxide liner layer has a thickness of 1-30 angstroms.

According to some embodiments, the epitaxial semiconductor layer has a right-left symmetric, concave polygonal cross-section.

Another aspect of the invention provides a method for forming a semiconductor device. A fin structure is provided on a substrate. An epitaxial semiconductor layer is then formed over an upper part of the fin structure. After forming the epitaxial semiconductor layer, a lower portion of the epitaxial semiconductor layer is etched, thereby forming an undercut.

According to some embodiments, the fin structure protrudes from the substrate in a first direction, and the undercut has a surface parallel to a third direction perpendicular to the first direction.

According to some embodiments, the undercut comprises a curved surface.

According to some embodiments, the substrate comprises silicon.

According to some embodiments, the fin structure comprises silicon.

According to some embodiments, the semiconductor device is a PMOS transistor and the epitaxial semiconductor layer comprises compressively stressed silicon germanium.

According to some embodiments, the method further the step of forming an oxide liner layer conformally covering the undercut and the step of forming an isolation structure around the fin structure, wherein the oxide liner layer is in direct contact with the isolation structure.

According to some embodiments, the oxide liner layer comprises silicon dioxide.

According to some embodiments, the oxide liner layer has a thickness of 1-30 angstroms.

According to some embodiments, the epitaxial semiconductor layer has a right-left symmetric, concave polygonal cross-section.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic layout diagram of a finFET device according to an embodiment of the present invention.

FIG. 2 is a schematic cross-sectional view taken along line I-I′ shown in FIG. 1.

FIG. 3 to FIG. 6 are schematic diagrams of the manufacturing method of the finFET device according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

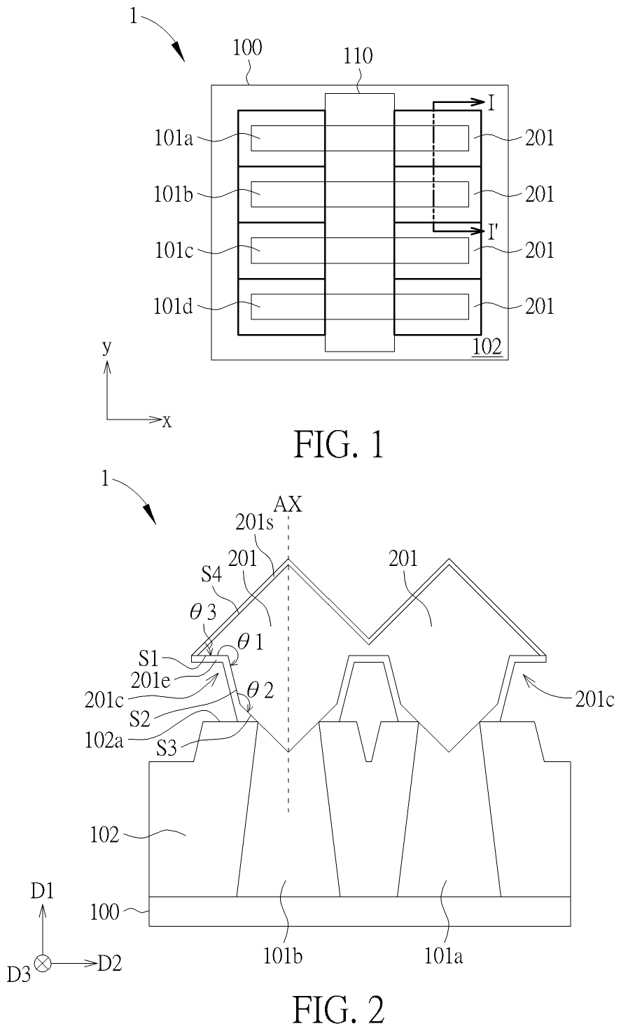

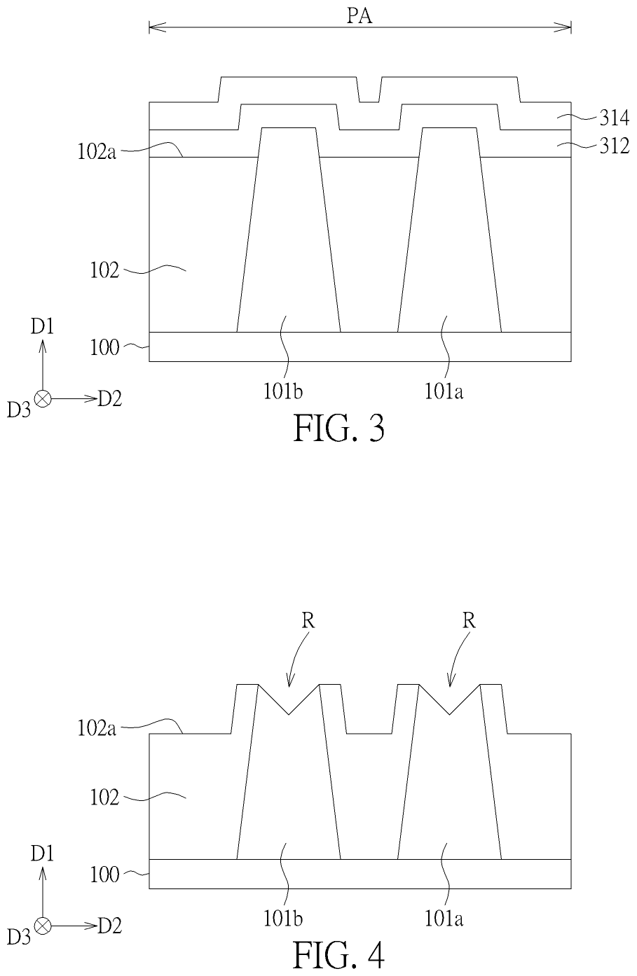

Please refer to FIG. 1 and FIG. 2. FIG. 1 is a schematic layout diagram of a fin field effect transistor (finFET) device according to an embodiment of the present invention, and FIG. 2 is a schematic cross-sectional view taken along line I-I′ in FIG. 1. As shown in FIG. 1 and FIG. 2, the FinFET device 1 may include a plurality of fin structures 101a-101d disposed on a semiconductor substrate 100. The plurality of fin structures 101a-101d may be surrounded by the isolation structure 102. For example, the isolation structure 102 may be a shallow trench isolation (STI) structure. The isolation structure 102 may include a silicon dioxide layer, but is not limited thereto. According to an embodiment of the present invention, for example, the semiconductor substrate 100 may include a silicon substrate, but is not limited thereto. According to an embodiment of the present invention, for example, the semiconductor substrate 100 may include silicon. According to an embodiment of the present invention, the plurality of fin structures 101a-101d may include silicon.

According to an embodiment of the present invention, as shown in FIG. 1, the plurality of fin structures 101a-101d may extend along the reference x-axis direction and protrude from the upper surface of the isolation structure 102. A gate structure 110 is disposed on the plurality of fin structures 101a-101d, extending along the reference y-axis direction. According to an embodiment of the present invention, the gate structure 110 may be a metal gate, but is not limited thereto. According to an embodiment of the present invention, for example, the finFET device 1 may be a PMOS transistor. An epitaxial semiconductor layer 201 may be formed on the plurality of fin structures 101a-101d on each of the opposite sides of the gate structure 110. According to an embodiment of the present invention, for example, the epitaxial semiconductor layer 201 may include compressively stressed silicon germanium.

According to an embodiment of the present invention, as shown in FIG. 2, the fin structures 101a and 101b protrude from the substrate 100 along the first direction D1. According to an embodiment of the present invention, the epitaxial semiconductor layer 201 protrudes from the upper surface 102a of the isolation structure 102. According to an embodiment of the present invention, the epitaxial semiconductor layer 201 has an undercut 201c, and the undercut 201c has a surface S1 parallel to the third direction D3 that is perpendicular to the first direction D1. In some embodiments, the surface S1 may be parallel to the second direction D2. In some embodiments, the surface S1 may be a curved surface. According to an embodiment of the present invention, the first direction D1 is not parallel to the second direction D2. According to an embodiment of the present invention, the first direction D1 intersects or crosses the second direction D2. According to an embodiment of the present invention, the first direction D1 is perpendicular to the second direction D2.

According to an embodiment of the present invention, the undercut 201c further include a surface S2 connected to the surface S1 and lower than the surface S1. According to an embodiment of the present invention, the surface S2 is not parallel to the first direction D1. According to an embodiment of the present invention, the surface S2 is not perpendicular to the second direction D2. According to an embodiment of the present invention, an interior angle ⊖1 between the surface S1 and the surface S2 is greater than 180 degrees.

According to an embodiment of the present invention, the epitaxial semiconductor layer 201 has a surface S3 connected to the surface S2 and lower than the surface S2. According to an embodiment of the present invention, the surface S3 is not parallel to the first direction D1. According to an embodiment of the present invention, the surface S3 is not perpendicular to the second direction D2. According to an embodiment of the present invention, the interior angle ⊖2 between the surface S3 and the surface S2 is less than 180 degrees. According to an embodiment of the present invention, the epitaxial semiconductor layer 201 has a left-right symmetric profile with respect to the central axis AX. According to an embodiment of the present invention, the epitaxial semiconductor layer 201 has a left-right symmetric, concave polygonal cross-section.

According to an embodiment of the present invention, the epitaxial semiconductor layer 201 may include an inclined top surface S4. According to an embodiment of the present invention, the top surface S4 is not parallel to the first direction D1. According to an embodiment of the present invention, the top surface S4 is not perpendicular to the second direction D2. According to an embodiment of the present invention, an interior angle ⊖3 between the top surface S4 and the surface S1 is less than 90 degrees. According to another embodiment of the present invention, the undercut 201c may comprise a curved surface.

According to an embodiment of the present invention, as shown in FIG. 2, the semiconductor device 1 further includes an oxide liner layer 201e conformally covering the surface S1 and the surface S2 of the undercut 201c. The oxide liner layer 201e is in direct contact with the isolation structure 102. According to an embodiment of the present invention, the oxide liner layer 201e includes silicon dioxide. According to an embodiment of the present invention, the thickness of the oxide liner layer 201e is 1-30 angstroms. In addition, according to an embodiment of the present invention, the top surface S4 of the semiconductor device 1 may have a Si-rich SiGe layer 201s, and the silicon concentration of which is higher than that of the rest part of the epitaxial semiconductor layer 201.

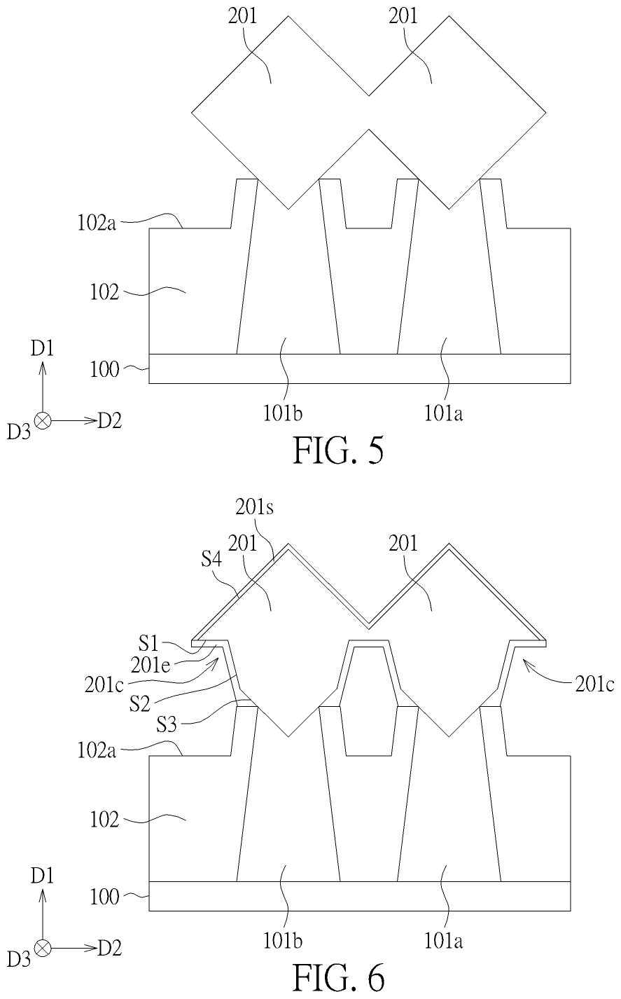

Please refer to FIG. 3 to FIG. 6, which are schematic diagrams of the manufacturing method of the finFET device according to the embodiment of the present invention. First, as shown in FIG. 3, the fin structures 101a and 101b and the isolation structure 102 are formed in the PMOS area PA of the substrate 100 by using, for example, lithography process, etching process and deposition process. The isolation structure 102 may be a shallow trench isolation structure. The fin structures 101a and 101b protrude from the upper surface 102a of the isolation structure 102. Next, a spacer layer 312 and a hard mask layer 314 are sequentially formed on the substrate 100. According to an embodiment of the present invention, for example, the spacer layer 312 may be a silicon oxide layer, and the hard mask layer 314 may be a silicon nitride layer. According to an embodiment of the present invention, the fin structures 101a and 101b protrude from the substrate 100 along the first direction D1.

As shown in FIG. 4, the spacer layer 312 and the hard mask layer 314 in the PMOS region PA are removed by using a lithography process and an etching process. An etching process is then performed to etch a recessed structure R at the top portions of the fin structures 101a and 101b protruding from the isolation structure 102. Subsequently, an ion implantation process may be performed to implant predetermined dopants into the fin structures 101a and 101b. Subsequent steps may include a pre-epitaxy cleaning process.

Subsequently, as shown in FIG. 5, epitaxial semiconductor layers 201 may be formed on the top portions of the fin structures 101a and 101b by using an epitaxial process. According to an embodiment of the present invention, the epitaxial semiconductor layer 201 protrudes from the upper surface 102a of the isolation structure 102. If the fin structures 101a and 101b are very close to each other, the epitaxial semiconductor layers 201 of the fin structures 101a and 101b may be connected to each other. According to an embodiment of the present invention, for example, the epitaxial semiconductor layer 201 includes compressively stressed silicon germanium. At this point, the epitaxial semiconductor layer 201 has a diamond-like or rhombus-shaped cross section.

As shown in FIG. 6, after the epitaxial semiconductor layer 201 are formed, a recessing process is performed to etch the lower part of the epitaxial semiconductor layer 201, thereby forming an undercut 201c. According to an embodiment of the present invention, the above-mentioned recessing process may include dry etching, wet etching, annealing, or a combination thereof. According to an embodiment of the present invention, the undercut 201c may include a surface S1 parallel to the third direction D3 that is perpendicular to the first direction D1. In some embodiments, the surface S1 may be parallel to the second direction D2. In some embodiments, the surface S1 may be a curved surface. According to an embodiment of the present invention, the first direction D1 is not parallel to the second direction D2. According to an embodiment of the present invention, the first direction D1 intersects the second direction D2. According to an embodiment of the present invention, the first direction D1 is perpendicular to the second direction D2.

According to an embodiment of the present invention, the undercut 201c may further include a surface S2 connected to the surface S1 and lower than the surface S1. According to an embodiment of the present invention, the surface S2 is not parallel to the first direction D1. According to an embodiment of the present invention, the surface S2 is not perpendicular to the second direction D2. According to an embodiment of the present invention, the interior angle ⊖1 between the surface S1 and the surface S2 is greater than 180 degrees.

According to an embodiment of the present invention, the epitaxial semiconductor layer 201 may include a surface S3 connected to the surface S2 and lower than the surface S2. According to an embodiment of the present invention, the surface S3 is not parallel to the first direction D1. According to an embodiment of the present invention, the surface S3 is not perpendicular to the second direction D2. According to an embodiment of the present invention, the interior angle ⊖2 between the surface S3 and the surface S2 is less than 180 degrees. According to an embodiment of the present invention, the epitaxial semiconductor layer 201 has a left-right symmetric profile with respect to the central axis AX (shown in FIG. 2). According to an embodiment of the present invention, the epitaxial semiconductor layer 201 has a left-right symmetric, concave polygonal cross-section.

According to an embodiment of the present invention, the epitaxial semiconductor layer 201 has an inclined top surface S4. According to an embodiment of the present invention, the top surface S4 is not parallel to the first direction D1. According to an embodiment of the present invention, the top surface S4 is not perpendicular to the second direction D2. According to an embodiment of the present invention, the interior angle ⊖3 between the top surface S4 and the surface S1 is less than 90 degrees. According to another embodiment of the present invention, the undercut 201c may have a curved surface.

According to an embodiment of the present invention, the surface S1 and the surface S2 may be formed with an oxide liner layer 201e. The oxide liner layer 201e conformally covers the surface S1 and the surface S2 of the undercut 201c. The oxide liner layer 201e is in direct contact with the isolation structure 102. According to an embodiment of the present invention, the oxide liner layer 201e may comprise silicon dioxide. According to an embodiment of the present invention, the thickness of the oxide liner layer 201e is 1-30 angstroms. In addition, according to an embodiment of the present invention, a Si-rich SiGe layer 201s may be formed on the top surface S4, and the silicon concentration of which is higher than that of the rest part of the epitaxial semiconductor layer 201. The Si-rich SiGe layer 201s on the top surface S4 can lead to a faster etching rate of the lower part of the epitaxial semiconductor layer 201 during the aforementioned recessing process, thereby forming the undercut 201c.

The present disclosure can effectively improve the operating performance of the PMOS fin field effect transistor by forming a compressively stressed silicon germanium layer with an undercut in the source or drain region of the PMOS fin field effect transistor.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a fin structure disposed on a substrate; and
an epitaxial semiconductor layer disposed over an upper part of the fin structure and having an undercut.

2. The semiconductor device of claim 1, wherein the fin structure protrudes from the substrate in a first direction, wherein the undercut has a surface parallel to a third direction perpendicular to the first direction.

3. The semiconductor device of claim 1, wherein the undercut comprises a curved surface.

4. The semiconductor device of claim 1, wherein the substrate comprises silicon.

5. The semiconductor device of claim 1, wherein the fin structure comprises silicon.

6. The semiconductor device of claim 1, wherein the semiconductor device is a PMOS transistor and the epitaxial semiconductor layer comprises compressively stressed silicon germanium.

7. The semiconductor device of claim 1 further comprising:
an oxide liner layer conformally covering the undercut; and
an isolation structure around the fin structure, wherein the oxide liner layer is in direct contact with the isolation structure.

8. The semiconductor device of claim 7, wherein the oxide liner layer comprises silicon dioxide.

9. The semiconductor device of claim 7, wherein the oxide liner layer has a thickness of 1-30 angstroms.

10. The semiconductor device of claim 1, wherein the epitaxial semiconductor layer has a right-left symmetric, concave polygonal cross-section.

11. A method for forming a semiconductor device, comprising:
providing a fin structure on a substrate;
forming an epitaxial semiconductor layer over an upper part of the fin structure; and
after forming the epitaxial semiconductor layer, etching a lower portion of the epitaxial semiconductor layer, thereby forming an undercut.

12. The method of claim 11, wherein the fin structure protrudes from the substrate in a first direction, wherein the undercut has a surface parallel to a third direction perpendicular to the first direction.

13. The method of claim 11, wherein the undercut comprises a curved surface.

14. The method of claim 11, wherein the substrate comprises silicon.

15. The method of claim 11, wherein the fin structure comprises silicon.

16. The method of claim 11, wherein the semiconductor device is a PMOS transistor and the epitaxial semiconductor layer comprises compressively stressed silicon germanium.

17. The method of claim 11 further comprising:
forming an oxide liner layer conformally covering the undercut; and
forming an isolation structure around the fin structure, wherein the oxide liner layer is in direct contact with the isolation structure.

18. The method of claim 17, wherein the oxide liner layer comprises silicon dioxide.

19. The method of claim 17, wherein the oxide liner layer has a thickness of 1-30 angstroms.

20. The method of claim 11, wherein the epitaxial semiconductor layer has a right-left symmetric, concave polygonal cross-section.
